(19) United States
(12) Patent Application Publication
(10) Pub. No.: US 2024/0120317 A1
(43) Pub. Date: Apr. 11, 2024

(54) SEMICONDUCTOR DEVICE INCLUDING VERTICALLY INTERCONNECTED SEMICONDUCTOR DIES

(71) Applicant: Western Digital Technologies, Inc., San Jose, CA (US)

(72) Inventors: Cheng-Hsiung Yang, Taichung (TW); Chien Te Chen, Taichung (TW); Cong Zhang, Shanghai (CN); Ching-Chuan Hsieh, Taichung (TW); Yu-Ying Tan, Taichung (TW); Juan Zhou, Shanghai (CN); Ai-wen Wang, Taichung (TW); Yih-Fran Lee, Taichung (TW); Yu-Wen Huang, Taichung (TW)

(73) Assignee: Western Digital Technologies, Inc., San Jose, CA (US)

(21) Appl. No.: 18/221,497

(22) Filed: Jul. 13, 2023

Related U.S. Application Data
(60) Provisional application No. 63/413,512, filed on Oct. 5, 2022.

(51) Int. Cl. H01L 25/065; H01L 23/00; H01L 23/29; H01L 23/31; H01L 23/498

(52) U.S. Cl. CPC H01L 25/0657; H01L 23/293; H01L 23/3107; H01L 23/49838; H01L 24/08; H01L 24/16; H01L 24/48; H01L 24/97; H01L 2224/08148; H01L 2224/16227; H01L 2224/16238; H01L 2224/48229; H01L 2224/97; H01L 2225/0651; H01L 2225/06517; H01L 2225/06548; H01L 2225/06551; H01L 2225/06562; H01L 2924/1433; H01L 2924/14361; H01L 2924/1438

(57) ABSTRACT

A fan-out semiconductor device includes stacked semiconductor dies having die bond pads arranged in columns exposed at a sidewall of the stacked semiconductor dies. The stacked dies are encapsulated in a photo imageable dielectric (PID) material, which is developed to form through-hole cavities that expose the columns of bond pads of each die at the sidewall. The through-hole cavities are plated or filled with an electrical conductor to form conductive through-holes coupling die bond pads within the columns to each other.

### CLAIM OF PRIORITY

The present application claims priority from U.S. Provisional Patent Application No. 63/413,512, entitled “SEMICONDUCTOR DEVICE INCLUDING VERTICALLY INTERCONNECTED SEMICONDUCTOR DIESS,” filed Oct. 5, 2022, which is incorporated by reference herein in its entirety.

### BACKGROUND

The strong growth in demand for portable consumer electronics is driving the need for high-capacity storage devices. Non-volatile semiconductor memory devices, such as flash memory storage cards, are widely used to meet the ever-growing demands on digital information storage and exchange. Their portability, versatility and rugged design, along with their high reliability and large capacity, have made such memory devices ideal for use in a wide variety of electronic devices, including for example digital cameras, digital music players, video game consoles, PDAs, cellular telephones and solid-state drives.

Semiconductor memory may be provided within a semiconductor package, which protects the semiconductor memory and enables communication between the memory and a host device. Examples of semiconductor packages include system-in-a-package (SiP) or multichip modules (MCM), where a plurality of die are mounted and interconnected on a small footprint substrate. The die in such packages are often stacked in a stepped offset pattern so that the die bond pads of each die are exposed at the stepped edge of the die stack. Wire bonds may then be formed between corresponding die bond pads of the die in the die stack, and to the substrate to allow signal exchange to/from select die in the die stack.

Some memory and IC companies are moving away from wire bonding toward an emerging technology that uses through silicon vias (TSV), in which the wire bonds are replaced by metal or conductive traces running through a wafer or die from top to bottom. This allows wafers or chips to be stacked on top of each other and electrically and mechanically bonded. The ability to vertically stack semiconductor dies directly on top of each other in a semiconductor package has advantages, such as smaller footprint, lower impedance that allows higher data rates, die size reduction and reduced interconnect length, thus improving latency. However, using TSVs to implement vertically stacked semiconductor die packages is an expensive and time-intensive process, as TSVs must be formed in each semiconductor die individually in the vertical die stack.

### DESCRIPTION OF THE DRAWINGS

FIG. 1 is a flowchart for forming a semiconductor die from a wafer according to embodiments of the present technology.

FIG. 2 is a plan view of a first major surface of a first semiconductor wafer according to embodiments of the present technology.

FIG. 3 is a plan view of a semiconductor die from the wafer shown in FIG. 2 according to embodiments of the present technology.

FIG. 4 is an edge view of a semiconductor die from the wafer shown in FIG. 2 according to embodiments of the present technology.

FIG. 5 is a flowchart for forming a semiconductor device according to embodiments of the present technology.

FIG. 6 is an edge view of a number of semiconductor devices being assembled on a carrier at a first step in the assembly process according to embodiments of the present technology.

FIG. 7 is a cross-sectional edge view of a number of semiconductor devices being assembled on a carrier at a second step in the assembly process according to embodiments of the present technology.

FIG. 8 is a cross-sectional edge view of a number of semiconductor devices being assembled on a carrier at a third step in the assembly process according to embodiments of the present technology.

FIG. 9 is a cross-sectional edge view of a number of semiconductor devices being assembled on a carrier at a fourth step in the assembly process according to embodiments of the present technology.

FIG. 10 is a cross-sectional front view of a number of semiconductor devices being assembled on a carrier at the fourth step in the assembly process according to embodiments of the present technology.

FIG. 11 is a plan view of a semiconductor die stack and PID layer formed with conductive through-holes and contact pads on a top surface of the PID layer according to embodiments of the present technology.

FIG. 12 is a cross-sectional edge view of a number of semiconductor devices being assembled on a carrier at a fifth step in the assembly process according to embodiments of the present technology.

FIG. 13 is a cross-sectional edge view of a number of semiconductor devices being assembled on a carrier at a sixth step in the assembly process according to embodiments of the present technology.

FIG. 14 is a cross-sectional edge view of a finished semiconductor device according to embodiments of the present technology.

FIG. 15 is an edge view of a number of semiconductor devices being assembled on a carrier at a first step in the assembly process according to alternative embodiments of the present technology.

FIG. 16 is a cross-sectional edge view of a number of semiconductor devices being assembled on a carrier at a second step in the assembly process according to alternative embodiments of the present technology.

FIG. 17 is a cross-sectional edge view of a number of semiconductor devices being assembled on a carrier at a third step in the assembly process according to alternative embodiments of the present technology.

FIG. 18 is a cross-sectional edge view of a number of semiconductor devices being assembled on a carrier at a fourth step in the assembly process according to alternative embodiments of the present technology.

FIG. 19 is a cross-sectional edge view of a number of semiconductor devices being assembled on a carrier at a fifth step in the assembly process according to alternative embodiments of the present technology.

FIG. 20 is a cross-sectional edge view of a number of semiconductor devices being assembled on a carrier at a sixth step in the assembly process according to alternative embodiments of the present technology.

FIG. 21 is a cross-sectional edge view of a finished semiconductor device according to embodiments of the present technology.

FIG. 22 is a perspective view of a finished semiconductor device according to embodiments of the present technology.

FIG. 23 is a plan view of a finished semiconductor device according to an alternative embodiment of the present technology.

FIG. 24 is an edge view of a semiconductor device according to embodiments of the present technology mounted to a printed circuit board by solder balls.

FIG. 25 is an edge view of a semiconductor device according to embodiments of the present technology mounted to a printed circuit board by bond wires.

FIG. 26 is a perspective view of a semiconductor wafer stack comprised of multiple wafers according to further embodiments of the present technology.

FIG. 27 is a cross-sectional edge view of a single assembled stack of semiconductor dies diced from the wafer stack of FIG. 26.

### DETAILED DESCRIPTION

The present technology will now be described with reference to the figures, which in embodiments, relate to a fan-out semiconductor device which includes stacked semiconductor dies having die bond pads arranged in columns exposed at a sidewall of the stacked semiconductor dies. The stacked dies are encapsulated in a photo imageable dielectric (PID) material, which is developed to form through-hole cavities that expose the columns of bond pads of each die at the sidewall. The through-hole cavities are plated or filled with an electrical conductor to form conductive through-holes coupling die bond pads within the columns to each other. The conductive through-holes may be electrically redistributed to contact pads on a surface of the fan-out semiconductor device, which may be used to electrically couple the semiconductor device to a host device such as a printed circuit board.

In embodiments, dies may be vertically stacked on the temporary carrier to provide an integrated block having a minimal overall footprint. In further embodiments, the dies may be stacked with a stepped offset. In still further embodiments, whole wafers may be stacked on each other with corresponding dies in respective wafers vertically aligned.

It is understood that the present invention may be embodied in many different forms and should not be construed as being limited to the embodiments set forth herein. Rather, these embodiments are provided so that this disclosure will be thorough and complete and will fully convey the invention to those skilled in the art. Indeed, the invention is intended to cover alternatives, modifications and equivalents of these embodiments, which are included within the scope and spirit of the invention as defined by the appended claims. Furthermore, in the following detailed description of the present invention, numerous specific details are set forth in order to provide a thorough understanding of the present invention. However, it will be clear to those of ordinary skill in the art that the present invention may be practiced without such specific details.

The terms “top” and “bottom,” “upper” and “lower” and “vertical” and “horizontal,” and forms thereof, as may be used herein are by way of example and illustrative purposes only, and are not meant to limit the description of the technology inasmuch as the referenced item can be exchanged in position and orientation. Also, as used herein, the terms “substantially” and/or “about” mean that the specified dimension or parameter may be varied within an acceptable manufacturing tolerance for a given application. In one embodiment, the acceptable manufacturing tolerance is 0.15 mm, or alternatively ±2.5% of a given dimension.

For purposes of this disclosure, a connection may be a direct connection or an indirect connection (e.g., via one or more other parts). In some cases, when a first element is referred to as being connected, affixed, mounted or coupled to a second element, the first and second elements may be directly connected, affixed, mounted or coupled to each other or indirectly connected, affixed, mounted or coupled to each other. When a first element is referred to as being directly connected, affixed, mounted or coupled to a second element, then there are no intervening elements between the first and second elements (other than possibly an adhesive or melted metal used to connect, affix, mount or couple the first and second elements).

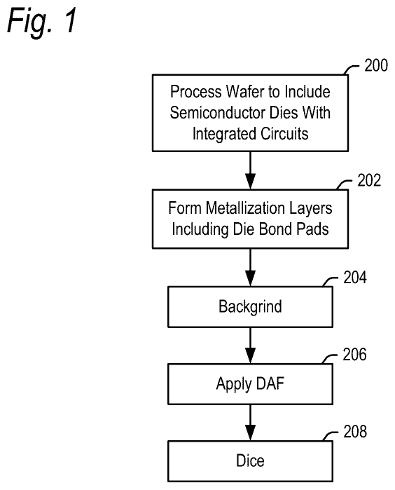

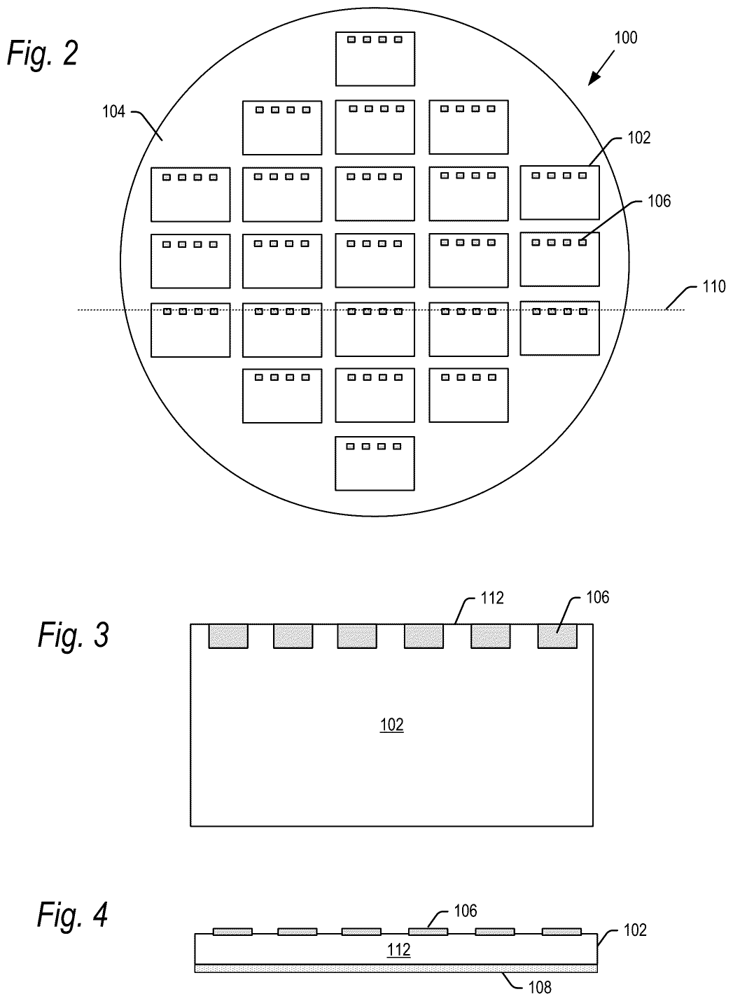

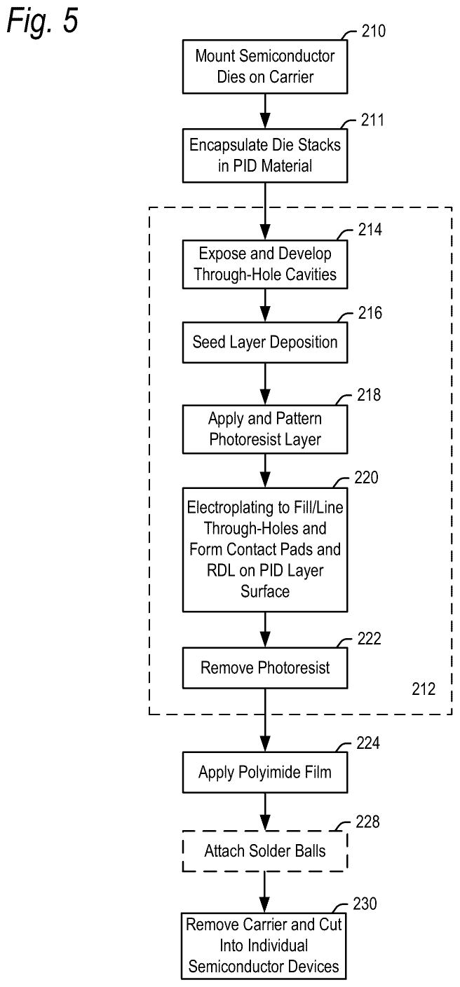

An embodiment of the present technology will now be explained with reference to the flowchart of FIGS. 1 and 5, and the views of FIGS. 2-4 and 6-25. In step 200, a semiconductor wafer 100 may be processed into a number of semiconductor dies 102 as shown in FIG. 2. Although not critical to the present technology, the semiconductor wafer 100 may start as an ingot of wafer material which may be monocrystalline silicon grown according to either a Czochralski (CZ) or floating zone (FZ) process. The wafer 100 may be formed of other materials and by other processes in further embodiments.

The semiconductor wafer 100 may be cut from the ingot and polished on both the first major surface (active surface) 104, and second major surface (inactive surface, not shown) opposite surface 104, to provide smooth surfaces. The first major surface 104 may undergo various processing steps to divide the wafer 100 into the respective semiconductor dies 102, and to form integrated circuits of the respective semiconductor dies 102 on and/or in the first major surface 104. In step 202, metallization layers may be formed in the wafer 100, including depositing metal contacts including die bond pads 106 exposed on the first major surface 104. The metallization step 202 may further include depositing metal interconnect layers and vias within the wafer. These metal interconnect layers and vias may be provided for transferring signals between the integrated circuits and the contact pads 106, and to provide structural support to the integrated circuits as is known.

After formation of the integrated circuits and bond pads, the wafer 100 may be flipped over and a backgrind process may be performed on the inactive surface to thin the wafer (step 204). A die attach adhesive film (DAF) layer 108 may then be applied to the thinned inactive surface (step 206), for example by spin coating. The wafer 100 may then again be flipped, and the wafer may be diced (step 208) to form individual semiconductor dies 102 as shown in the plan view of FIG. 3 and the edge view of FIG. 4.

The number of semiconductor dies 102 shown on wafer 100 in FIG. 2 is for illustrative purposes, and wafer 100 may include more semiconductor dies 102 than are shown in further embodiments. Similarly, the number and pattern of bond pads 106 on the semiconductor dies 102 in FIGS. 2-4 are shown for illustrative purposes, and the dies 102 may include bond pads 106 in different patterns and in different numbers than are shown in further embodiments.

While different patterns of die bond pads 106 are possible, it is a feature of the present technology that the die bond pads 106 be exposed at a vertical edge of the semiconductor dies 102. Thus, in step 208, the wafer is diced along horizontal cut lines (such as cut line 110 in FIG. 2) that pass through the die bond pad 106 on the first major surface 104. The result is die bond pads in the finished semiconductor dies 102 exposed at a vertical edge 112 of the dies. In embodiments, the die bond pads 106 may be the same size as conventional bond pads, or larger than conventional bond pads. In one example, the bond pads may be 70-150 microns (μm) square, though the bond pads may be larger or smaller than that, and may be rectangular (length greater than the width) in further embodiments. The metallization process may also or alternatively form the die bond pads that are the same thickness or thicker than conventional die bond pads, such as for example 1-50 μm, though the thickness may be lesser or greater than that in further embodiments.

The semiconductor dies 102 may for example be memory dies such as 2D NAND flash memory or 3D BiCS (Bit Cost Scaling), V-NAND or other 3D flash memory. However, dies 102 may be other types of dies, including for example a controller die such as an ASIC, or RAM such as an SDRAM, DDR SDRAM, LPDDR and GDDR.

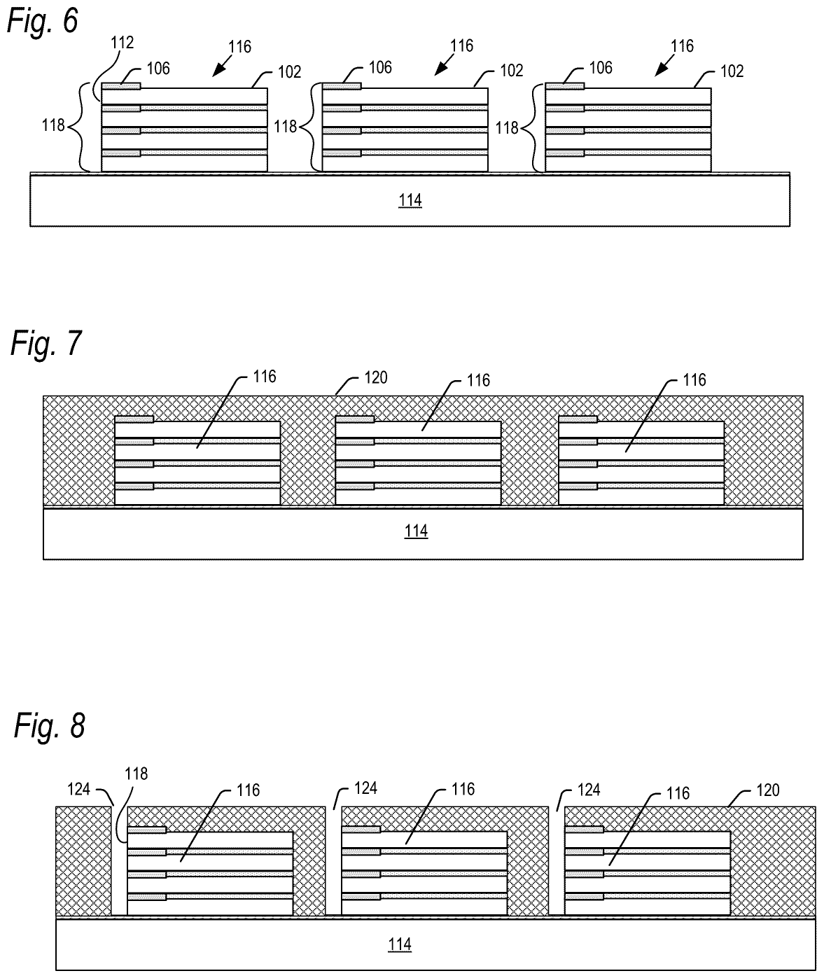

After the dies 102 are formed and diced from wafer 100, the dies 102 may then be packaged into semiconductor devices according to the present technology as will now be explained with reference to the flow chart of FIG. 5 and the views of FIGS. 6-25. In step 210, semiconductor dies 102 may be stacked on a temporary carrier 114 to form die stacks 116 as shown for example in FIG. 6. The carrier may be any of various materials, including for example Silicon, Silicon Dioxide, glass or a polymer. The dies may be adhered to the carrier 114 and each other by DAF layer 108 on the inactive surface of each die. Carrier 114 may alternatively or additionally include an adhesive release layer temporarily holding the stacks 116 on the carrier 114.

The figures show three stacks 116 of dies 102, and each stack including four semiconductor dies 102. It is understood that the number of stacks 116 on a carrier 114, and/or the number of dies in each stack 116, may vary in further embodiments. The dies on the carrier 114 may be arranged in a single line, or they may be arrayed in a two dimensional pattern on the carrier 114. The dies 102 in a given stack may come from the same or different wafers 100. Similarly, the dies on carrier 114 as a whole may come from the same or different wafers 100.

In one embodiment, the dies 102 in a stack 116 are mounted on carrier 114 so that the vertical edges 112 of each die in a stack align with each other to define a sidewall 118. In this embodiment, the sidewall 118 is a planar, vertical surface at each stack 116. The bond pads 106 of each of the dies in a stack are exposed at the vertical sidewall 118.

In step 211, the die stacks 116 may each be encapsulated in a photo imageable dielectric layer 120 as shown in FIG. 7. A photo imageable dielectric (PID) layer is a dielectric layer that can be patterned through a lithography process (e.g., by exposing the dielectric layer to a light source). The PID layer 120 may be formed of various photo-sensitive dielectric materials, such as Build-Up films or polymer compounds like Polyimide, Polyamide, Polybenzoxazole, or Benzocyclobutene. Other materials are contemplated. The PID layer 120 may be formed around the die stacks 116 on carrier 114 for example by placing carrier 114 in a mold chase into which the PID material is injected and hardened around the die stacks 116. Alternatively, the carrier 114 may be flipped over into a bath of powder or liquid PID material in an FFT (flow free thin) mold process and cured around the die stacks 116.

In step 212, the PID layer may be developed to form conductive through-holes down through the PID layer 120 adjacent each die stack 116. Further details of step 212 will now be explained with reference to steps 214-222 and FIGS. 8-11. FIGS. 8-11 show the formation of a single conductive through-hole in each die stack 116 in cross-section for clarity. A number of such conductive through-holes may be formed along the edge of each die stack 116 adjacent each column of die bond pads 106 (i.e., into the page of FIG. 8 and as shown in FIG. 10).

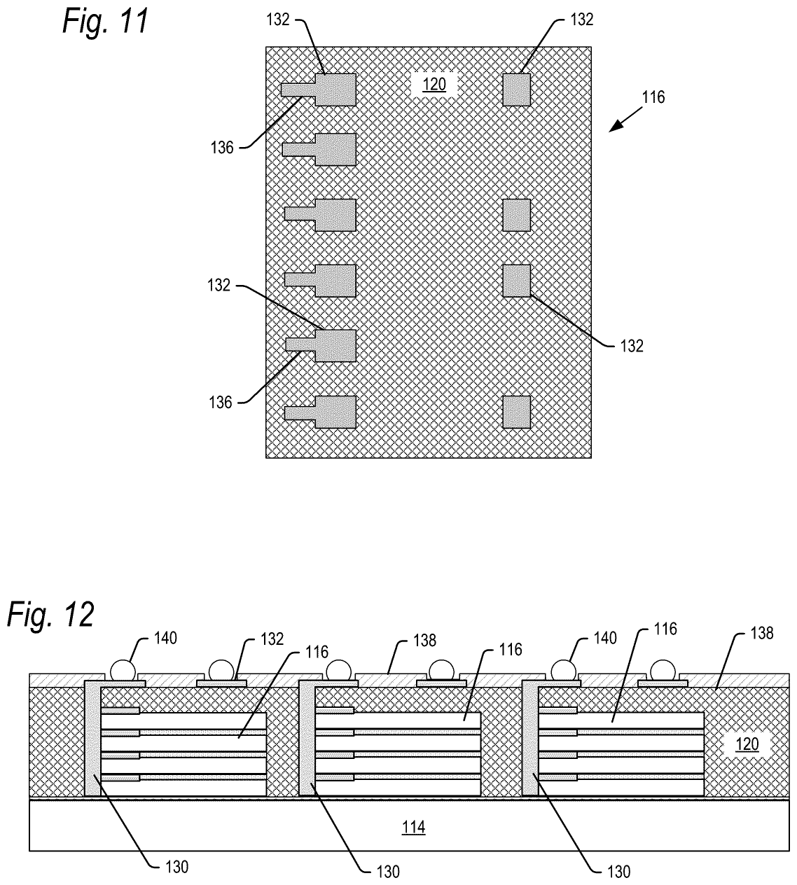

In step 214, the PID layer 120 may be processed by photo imaging to expose and develop through-hole cavities 124 down through the PID layer as shown in FIG. 8. In this embodiment, the through-hole cavities 124 may have a uniform cross-sectional shape along a length of the through-hole cavities 124. The through-hole cavities 124 may be rectangular, semicircular or other shapes in cross-section. The photo imaging process may be precisely controlled to ensure the through-hole cavities 124 in each stack 116 are formed directly adjacent the sidewall 118 in each stack, and aligned laterally with each column of die bond pads 106 in each semiconductor die 102 (as shown in FIG. 11). As shown, each through-hole cavity 124 may be etched vertically down through each stack 116 until the through-hole cavity 124 reaches at least to the die bond pad 106 on the last (bottommost) die 102 in each stack 116. The photo imaging process removes the PID material, but does not affect the semiconductor dies 102 or the die bond pads 106. As a result, the columns of die bond pads 106 on vertical sidewall 118 in each stack 116 are exposed at the through-hole cavities 124.

In step 216, a seed layer may be deposited over all surfaces within the through-hole cavities 124. The seed layer may be any of a variety of conductive materials such as copper deposited by a variety of techniques including by physical vapor deposition (PVD), electrografting (eG) or other sputtering technique. In step 218, a layer of photoresist may be applied over the surface of the PID layer 120 in each stack 116. The photoresist layer may also be patterned in step 218 using a mask to develop and remove portions of the photoresist layer to leave areas of the PID layer 120 in each stack exposed. These exposed areas include over the lined through-hole cavities 124 and areas on a top surface 136 of the PID layer where contact pads and a redistribution layer are to be formed as explained below.

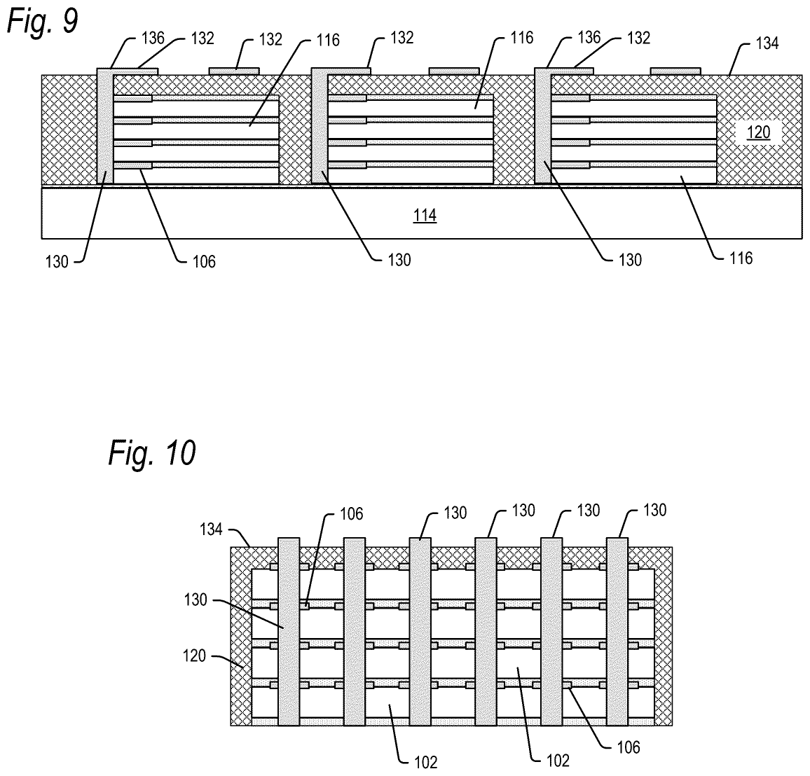

In step 220, an electrical conductor may be formed on the exposed areas of the PID layer 120. Part of step 220 includes plating or filling the through-hole cavities 124 to form conductive through-holes 130 as shown in the cross-sectional edge view of FIG. 9 and in the cross-sectional front view of FIG. 10. The electrical conductor in conductive through-holes 130 may be a variety of conductive materials, including for example copper or tungsten, applied by various processes including electroplating or with solder using capillary action.

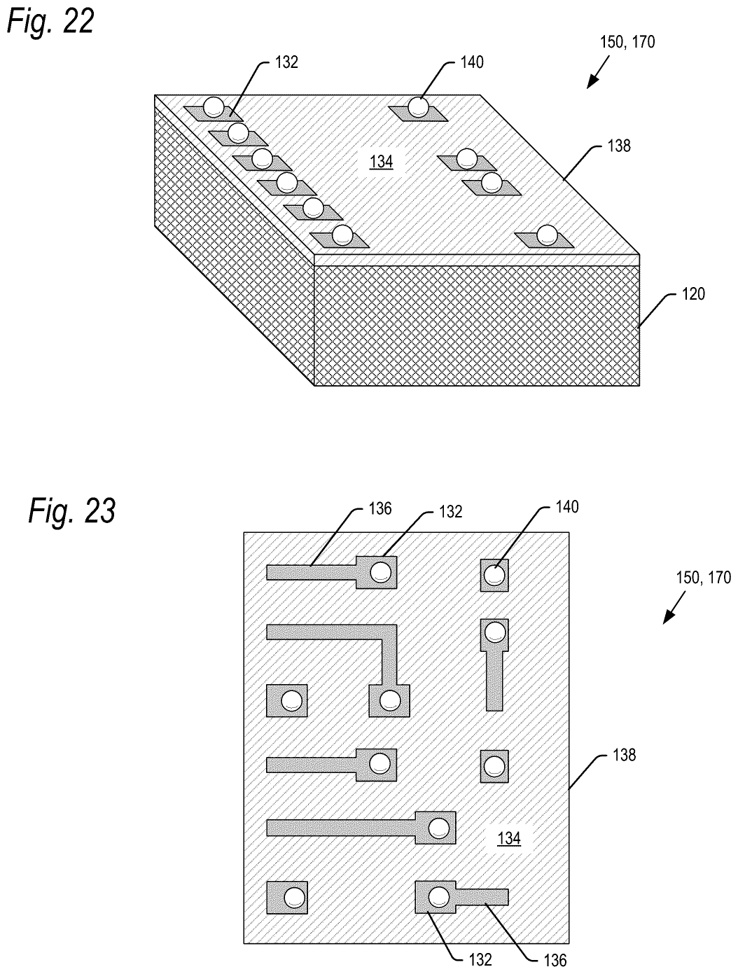

Step 220 may also include the formation of input/output (I/O) contact pads 132 and an RDL (redistribution layer) 136 on exposed areas of the top surface 134 of the PID layer 120. At least some of the contact pads 132 may be electrically coupled to the conductive through-holes 130 by RDL 136. FIG. 11 shows a plan view of a single die stack 116 within the PID layer 120 showing a pattern of contact pads 132 and RDL 136. However, the pattern of contact pads 132 and RDL 136 shown in FIGS. 9 and 11 is by way of example only. There may be many more contact pads 132 and, as explained below with respect to FIGS. 22 and 23, the contact pads 132 may be in a variety of positions, connected to the conductive through-holes 130 by various RDL 136 patterns. Additionally, while the contact pads 132 as shown in the figures are rectangular, the contact pads may alternatively or preferentially be shaped as circular. After formation of the plated/filled conductive through-holes 130, contact pads 132 and RDL 136, the photoresist pattern may be removed in step 222.

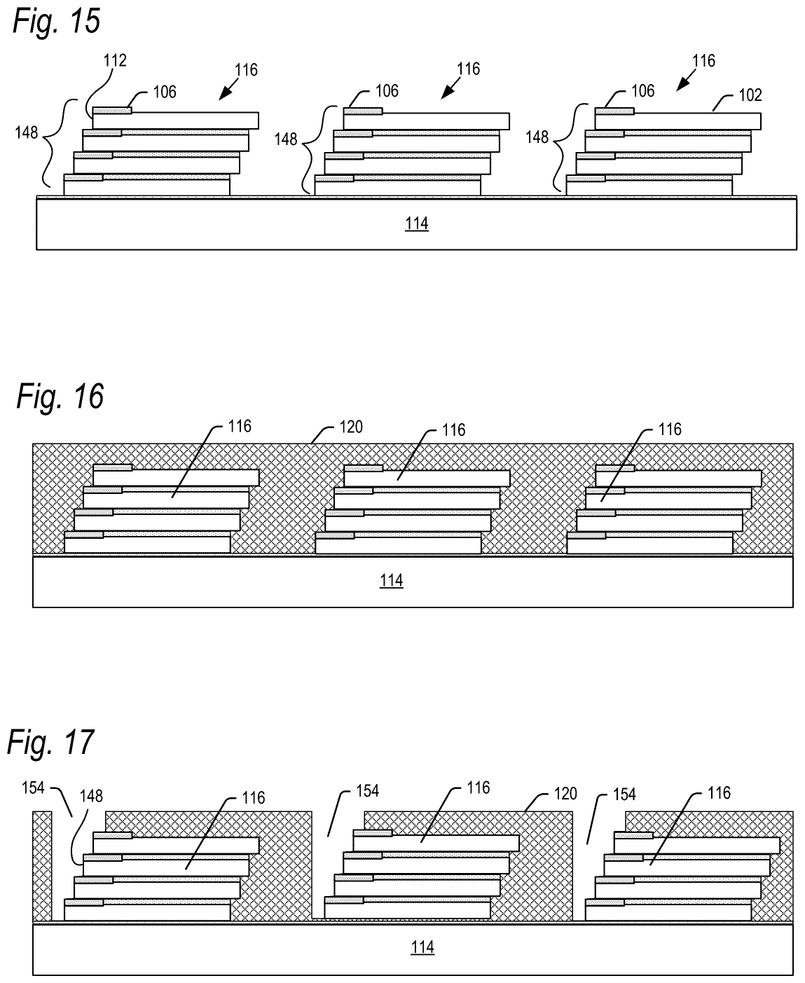

FIG. 10 shows a cross section through a single die stack 116 within the PID layer 120. As seen in FIGS. 9 and 10, a conductive through-hole 130 lies in contact with each bond pad 106 in a column of vertically aligned bond pads 106 in a stack 116 so as to electrically couple corresponding die bond pads 106 in each die 102 in stacks 116. As used herein, ‘corresponding’ dies and ‘corresponding’ die bond pads refers to dies and die bond pads in different levels of a stack of dies that are directly vertically aligned with each other, or aligned with each other with a stepped offset (as described below with respect to FIGS. 15-21).

In step 224, a protective layer 138 such as a dielectric polyimide film may be applied on the upper surface 134 of the PID layer 120 as shown in the cross-sectional edge view of FIG. 12. The contact pads 132 in the upper surface 134 of the PID layer 120 may be exposed through openings in the protective layer 138. In step 228, solder balls 140 may be affixed to contact pads 132. Step 228 is shown in phantom as solder balls 140 may be omitted in embodiments, as explained below with reference to FIG. 25.

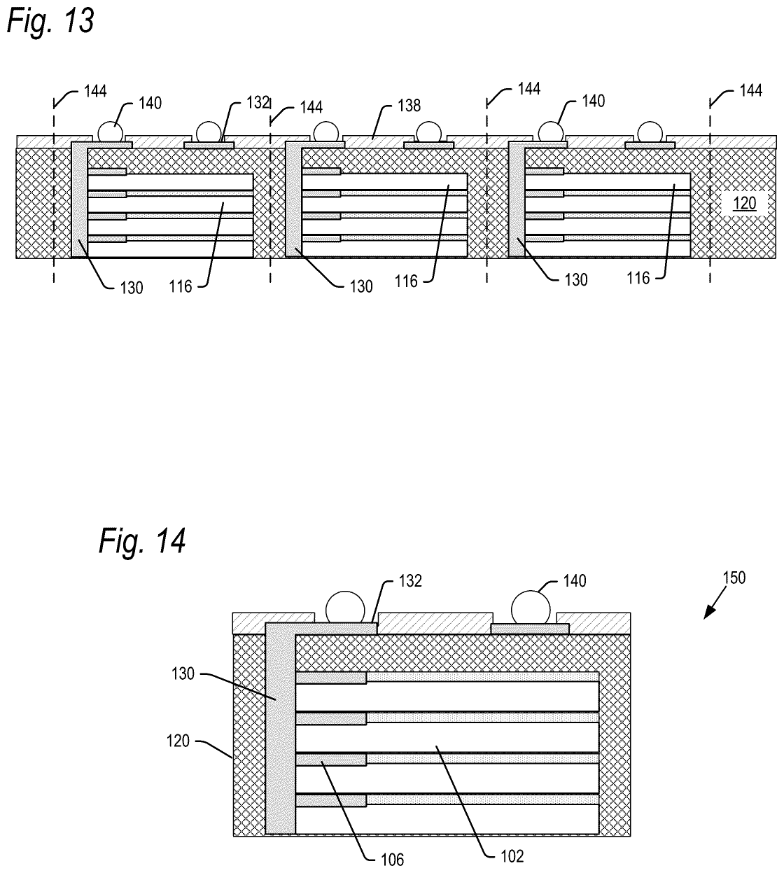

In step 230, the temporary carrier 114 may be removed, and the block PID layer 120 may be cut along planes 144 (into the page of FIG. 13) to form completed semiconductor devices. Severing the PID layer 120 in this manner leaves each semiconductor device with a die stack 116 surrounded on at least four vertical surfaces and a top surface by the PID layer 120. The PID layer 120 may be cut along planes 144 by any of various methods including saw blade, laser and water jet.

The semiconductor die stacks 116 may be formed closely to each other on carrier 114 (e.g., spaced 50 to 100 μm) so that, once cut in step 230, there is only a small amount of PID layer 120 around edges of the die stack 116. The spacing between die stacks may be larger or smaller than that in further embodiments. It is also possible that the die stacks be spaced further apart, and two cuts be made between adjacent die stacks 116 to again leave only a small amount of PID layer 120 around edges of each die stack 116.

An example of a completed semiconductor device 150 is shown in cross-section in FIG. 14. The completed semiconductor device 150 may be a fan-out semiconductor package where the signals to/from the individual bond pads 106 on each die 102 in the device 150 are redistributed by the conductive through-holes 130 and RDL 136 to the I/O contact pads 132 on an outer surface of semiconductor device 150. The semiconductor dies 102 are vertically stacked with complete overlap, and the footprint of the PID layer 120 (and overall device 150) may be only slightly larger than the footprint of the die stack 116 to provide a fan-out semiconductor device 150 of minimal footprint. As explained below, the semiconductor device 150 may be physically mounted and electrically coupled to a host device such as a printed circuit board.

A further embodiment of a semiconductor device will now be described with reference to FIGS. 15-21. This embodiment is similar to that described above. However, in this embodiment, the dies 102 are stacked on the temporary carrier 114 with a slight stepped offset, as shown for example in the cross-sectional edge view of FIG. 15. In embodiments, the offset between stacked dies 102 may be 5 to 50 μm, though the offset may be greater or lesser than that in further embodiments. Again, the number of stacks 116 in FIG. 15 and the number of dies 102 in each stack 116 is by way of example and may vary in further embodiments.

Each die 102 includes a vertical edge 112. In this embodiment, the dies 102 in a stack 116 are mounted on carrier 114 so that the vertical edges 112 of each die in a stack define a sidewall 148. The sidewall 148 is stepped at an angle, based on the offset of each of the dies 102 in stack 116. It is a feature of this embodiment that both vertical and horizontal portions of each die bond pad 106 are exposed at sidewall 148.

As shown in the cross-sectional edge view of FIG. 16, the die stacks 116 may each be encapsulated in a PID layer 120 as described above. Through-hole cavities 154 may next be developed down through the PID layer 120 adjacent each die stack 116 as shown in the cross-sectional edge view of FIG. 17. The through-hole cavities 154 may be formed as described above with respect to through-hole cavities 124. However, given the die offset in stacks 116, the through-hole cavities 154 have a first vertical sidewall (distal from the stacks 116) and stepped sidewall 148 (adjacent to each of the stacks 116). Thus, the through-hole cavities 154 are wider at a top of the stacks 116, and step narrower at the bottom of the stacks. As noted above, an etching process is selected that etches the PID material without affecting the semiconductor dies 102 or bond pads 106. As above, the through-hole cavities 154 may be aligned laterally with each column of die bond pads 106 in each semiconductor die 102.

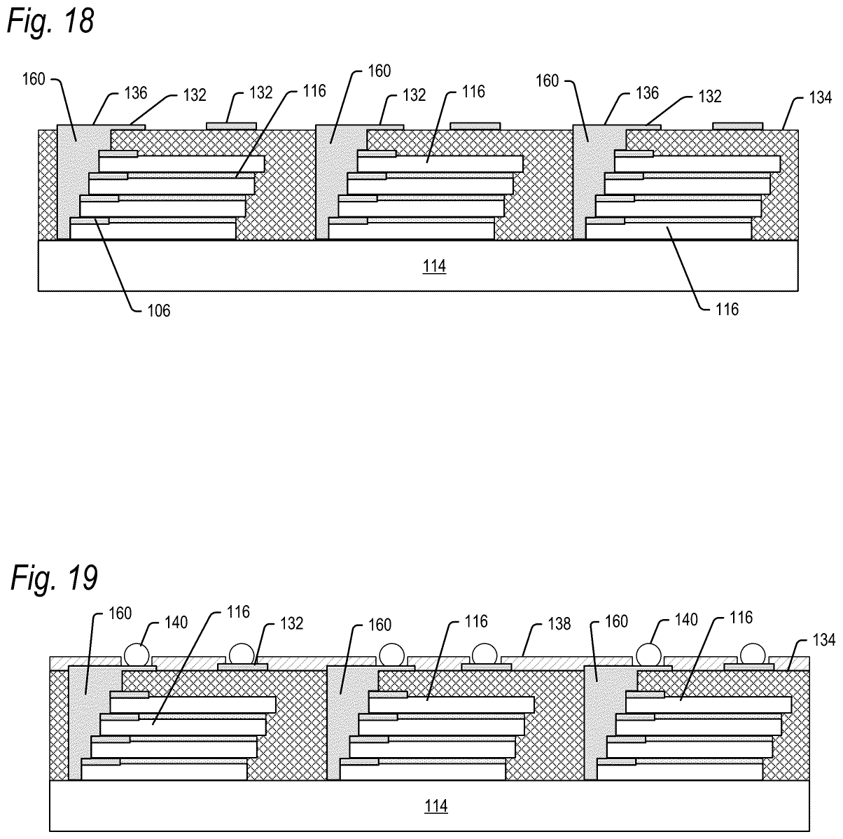

The through-hole cavities 154 may next undergo lining and plating processes as described above to coat or fill the through-hole cavities 154 with an electrical conductor such as for example copper or tungsten. The resulting conductive through-holes 160 are shown in FIG. 18. As above, each conductive through-hole 160 lies in contact with a column of bond pads 106 in a stack 116. Specifically, a conductive through-hole 160 contacts a vertical portion of each bond pad 106, and a horizontal portion of each bond pad 106 exposed by the offset of the next-higher semiconductor die 102 in the stack. Thus, corresponding (vertically aligned) die bond pads 106 in each die 102 are electrically coupled in stacks 116.

Input/output (I/O) contact pads 132 may also be formed on a top surface 134 of the PID layer 120 as described above. The contact pads 132 may be electrically coupled to the conductive through-holes 160 by an RDL 136 (FIG. 18). Further details of RDL 136 are provided below.

As above, a protective layer 138 may next be applied on the upper surface 134 of the PID layer 120 as shown in the cross-sectional edge view of FIG. 19. The contact pads 132 in the upper surface 134 of the PID layer 120 may be exposed through openings in the protective layer 138. Solder balls 140 may also be affixed to the contact pads 132.

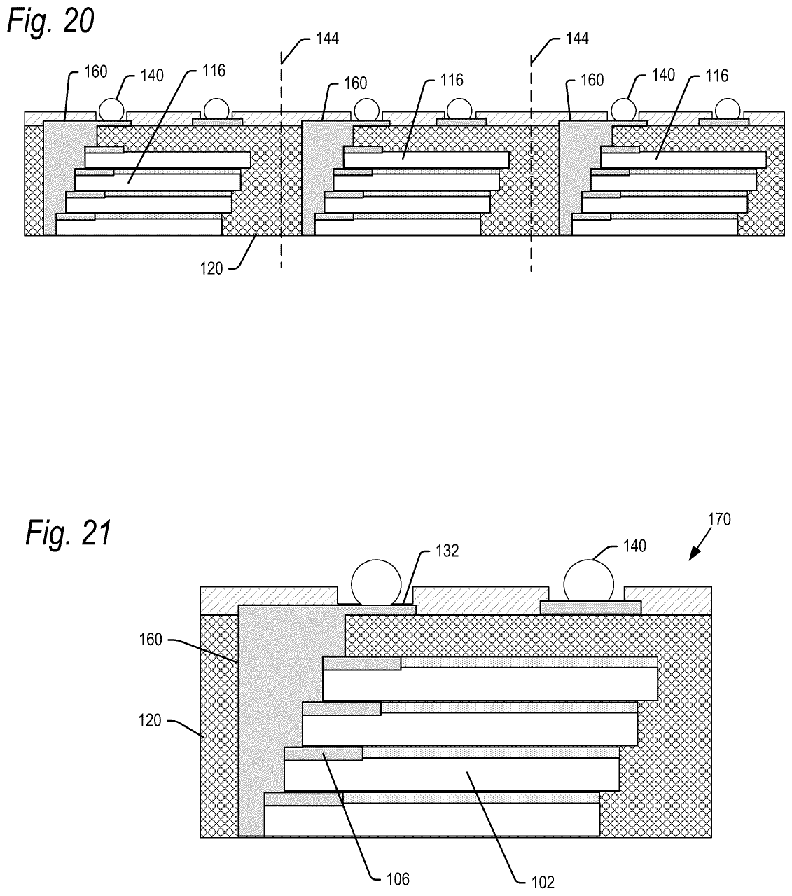

The temporary carrier 114 may then be removed, and the block PID layer 120 may be cut along lines through planes 144 (into the page of FIG. 20) as described above to form completed semiconductor devices 170 as shown in the cross-sectional view of FIG. 21.

The completed semiconductor device 170 may be a fan-out semiconductor package where the signals to/from the individual bond pads 106 on each die 102 in the device 170 are redistributed by the conductive through-holes 160 and RDL 136 to the I/O contact pads 132 on an outer surface of semiconductor device 150. Given the die offset within stacks 116, the semiconductor device 170 may have a slightly larger footprint than semiconductor device 150, though not necessarily. The die offset within the stacks provides an advantage of excellent electrical contact of the conductive through-holes 160 with each bond pad 106 (against both vertical and horizontal surfaces of each bond pad).

FIG. 22 is a perspective view of completed semiconductor device (either semiconductor device 150 or 170). The monolithic fan-out design provides a semiconductor device of minimal footprint. As noted above, the contact pads 132 on the upper surface of the device may be provided in any of a wide variety of positions. FIG. 22 shows a simple example where some of the bond pads are positioned directly above the conductive through-holes 130, 160. FIG. 22 is a plan view of either semiconductor device 150 or 170 where the contact pads 132 are distributed in different positions on the upper surface. RDL 136 is provided to electrically couple the distributed pattern of contact pads 132 with the conductive through-holes 130, 160 within the semiconductor device. Other patterns of contact pads 132 and RDL 136 are contemplated.

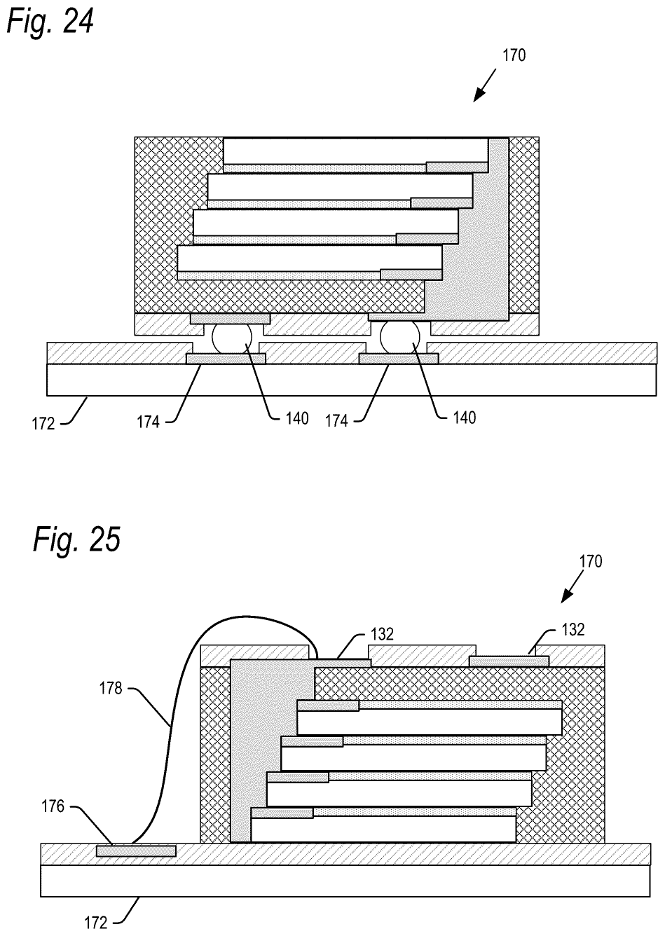

FIG. 24 is a cross-sectional view showing a completed semiconductor device according to the present technology mounted on, and electrically coupled to, a host device such as a printed circuit board (PCB) 172. In this example, a semiconductor device 170 is shown, but a semiconductor device 150 may alternatively be used. In this embodiment, the solder balls 140 are used to solder the device 170 to contact pads 174 on PCB 172 in a flip-chip configuration. FIG. 25 is a cross-sectional view showing a semiconductor device 170 mounted on PCB 172, and electrically coupled to contact pads 176 on PCB 172 by bond wires 178 formed by a wire bond capillary (not shown). The semiconductor device 150 may be wire bonded to the PCB 172 in the same manner in further embodiments.

In embodiments described, the finished semiconductor devices 150, 170 each include a single stack 116 of semiconductor dies 102. However, it is understood that the PID layer block may be cut so that each finished semiconductor device 150, 170 may include more than one stack 116 of semiconductor dies 102. In such embodiments, a semiconductor device 150, 170 may include a pair of stacks 116, three stacks 116 or four stacks 116, for example arranged in a two-by-two array. More than four stacks are also possible in a finished semiconductor device 150, 170.

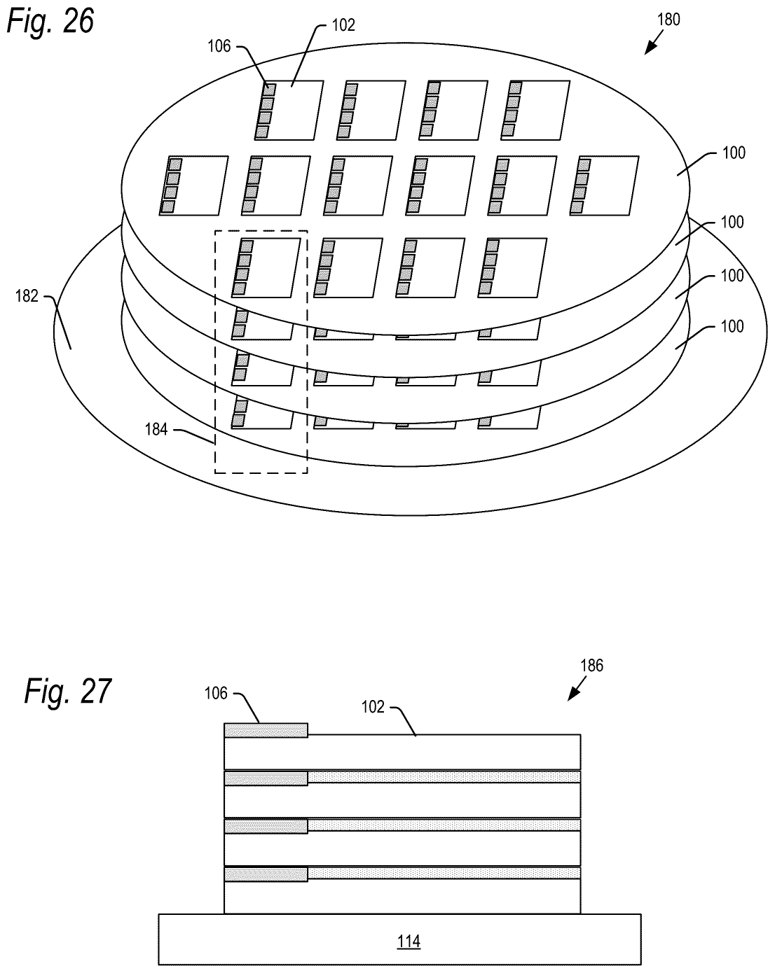

In embodiments described above, individual semiconductor dies 102 are mounted on each other to form a number of stacks 116 on temporary carrier 114. However, in a further embodiment, instead of mounting individual semiconductor dies on temporary carrier 114, a preassembled stack of semiconductor dies may be formed and the preassembled stack mounted on the temporary carrier 114. Such an embodiment will now be described with reference to the perspective view of FIG. 26 and the cross-sectional view of FIG. 27.

In this embodiment, semiconductor wafers 100 may be fabricated as described above. However, in this embodiment, instead of dicing the wafer upon completion, the semiconductor wafers 100 may be aligned and stacked on each other as shown in FIG. 26 to form a wafer stack 180. The wafer stack 180 may be supported on a temporary carrier 182. The number of wafers 100 in the wafer stack 180, the number of semiconductor dies 102 on each wafer 100, and the number of die bond pads 106 on each semiconductor die 102 shown in FIG. 26 are by way of example only and each may vary in further embodiments. Although the wafers 100 are shown with a slight spacing for clarity in FIG. 26, the wafers 100 would be stacked directly on top of each other. The wafers 100 may be adhered to each other by the DAF layer formed on the bottom of each wafer as described above, or laminated together by other methods.

In this embodiment, the dies 102 and die bond pads 106 are formed in the same corresponding positions on each wafer. That is, the corresponding dies 102 and die bond pads 106 on each wafer are in complete alignment with each other. Thus, for example, a group of dies within dashed box 184 in FIG. 26 stack on top of each other in the same manner as the dies 102 were stacked in stacks 116 described above. In this embodiment, the die bond pads 106 may be formed at the edge of each semiconductor die 102, though they need not be in further embodiments.

Once the wafer stack 180 is formed, the individual columns of corresponding dies may be diced from the wafer stack to form preassembled stacks 186 of semiconductor dies 102 as shown in the cross-sectional edge view of FIG. 27. These preassembled stacks 186 may then be affixed to temporary carrier 114 and then processed into semiconductor devices 150, as explained above with respect to the flowchart of FIG. 5 and the views of FIGS. 6-14. The assembly of the dies 102 into preassembled stacks 186 simplifies and shortens the processing of semiconductor devices 150 as compared to an embodiment where individual semiconductor dies are stacked on carrier 114 one at a time.

In summary, the present technology relates to a semiconductor device, comprising: a plurality of stacked semiconductor dies, the plurality of semiconductor dies together defining a sidewall; a plurality of die bond pads on the plurality of semiconductor dies and positioned at the sidewall; an encapsulant covering at least portions of the plurality of stacked semiconductor dies including the sidewall and the plurality of die bond pads; and conductive through-holes formed in through-hole cavities developed through at least one of the encapsulant and the plurality of semiconductor dies, the plurality of die bond pads exposed at the through-hole cavities, and a conductive through-hole of the conductive through-holes electrically coupling a group of corresponding die bond pads of the plurality of die bond pads.

In another example, the present technology relates to a semiconductor device, comprising: a plurality of stacked semiconductor dies, the plurality of semiconductor dies together defining a sidewall; a plurality of die bond pads on the plurality of semiconductor dies and arranged in columns at the sidewall; a photo imageable dielectric material covering at least portions of the plurality of stacked semiconductor dies including the sidewall and the plurality of die bond pads; and conductive through-holes formed in the photo imageable dielectric material, the plurality of die bond pads exposed to the conductive through-holes, and the conductive through-holes electrically coupling die bond pads on the columns of die bond pads together.

In a further example, the present technology relates to a semiconductor device, comprising: a plurality of stacked semiconductor dies, the plurality of semiconductor dies together defining a sidewall; a plurality of die bond pads on the plurality of semiconductor dies and arranged in columns at the sidewall; a photo imageable dielectric material covering at least portions of the plurality of stacked semiconductor dies including the sidewall and the plurality of die bond pads; and means formed through the photo imageable dielectric material for electrically coupling die bond pads on the columns of die bond pads together.

The foregoing detailed description of the invention has been presented for purposes of illustration and description. It is not intended to be exhaustive or to limit the invention to the precise form disclosed. Many modifications and variations are possible in light of the above teaching. The described embodiments were chosen in order to best explain the principles of the invention and its practical application to thereby enable others skilled in the art to best utilize the invention in various embodiments and with various modifications as are suited to the particular use contemplated. It is intended that the scope of the invention be defined by the claims appended hereto.

We claim:

1. A semiconductor device, comprising:
a plurality of stacked semiconductor dies, the plurality of semiconductor dies together defining a sidewall;
a plurality of die bond pads on the plurality of semiconductor dies and positioned at the sidewall;
an encapsulant covering at least portions of the plurality of stacked semiconductor dies including the sidewall and the plurality of die bond pads; and
conductive through-holes formed in through-hole cavities developed through the encapsulant, the plurality of die bond pads exposed at the through-hole cavities.

2. The semiconductor device of claim 1, wherein the sidewall is a planar sidewall.

3. The semiconductor device of claim 1, wherein the sidewall is a stepped, offset sidewall.

4. The semiconductor device of claim 1, wherein the through-hole cavities are through the encapsulant.

5. The semiconductor device of claim 1, further comprising a plurality of contact pads formed on a surface of the semiconductor device.

6. The semiconductor device of claim 5, further comprising a redistribution pattern on the surface of the semiconductor device, the redistribution pattern electrically coupling the plurality of contact pads to the conductive through-holes.

7. The semiconductor device of claim 6, wherein the surface is on a surface of the encapsulant.

8. The semiconductor device of claim 1, wherein the encapsulant comprises a photo imageable dielectric material.

9. The semiconductor device of claim 1, wherein the through-hole cavities have a uniform cross-sectional shape along a length of the through-hole cavities.

10. The semiconductor device of claim 1, wherein the through-hole cavities are wider at a top portion of the through-hole cavities than at a bottom portion of the through-hole cavities.

11. The semiconductor device of claim 1, wherein the conductive through-holes comprise an electrical conductor lining the through-hole cavities.

12. The semiconductor device of claim 1, wherein the conductive through-holes comprise an electrical conductor filling the through-hole cavities.

13. The semiconductor device of claim 1, wherein the plurality of semiconductor dies comprise one or more stacks of individual semiconductor dies.

14. The semiconductor device of claim 1, wherein the plurality of semiconductor dies comprise whole semiconductor wafers of semiconductor dies.

15. A semiconductor device, comprising:
a plurality of stacked semiconductor dies, the plurality of semiconductor dies together defining a sidewall;
a plurality of die bond pads on the plurality of semiconductor dies and arranged in columns at the sidewall;
a photo imageable dielectric material covering at least portions of the plurality of stacked semiconductor dies including the sidewall and the plurality of die bond pads; and
conductive through-holes formed in the photo imageable dielectric material, the plurality of die bond pads exposed to the conductive through-holes, and the conductive through-holes electrically coupling die bond pads on the columns of die bond pads together.

16. The semiconductor device of claim 15, wherein the plurality of stacked semiconductor dies comprise a stack of vertically aligned semiconductor dies and the sidewall is a planar sidewall.

17. The semiconductor device of claim 15, wherein the plurality of stacked semiconductor dies comprise a stack of semiconductor dies offset from each other with a stepped offset.

18. The semiconductor device of claim 17, wherein the conductive through-holes are wider at a first end of the conductive through-holes than at a second end of the conductive-through holes.

19. The semiconductor device of claim 15, wherein the plurality of stacked semiconductor dies comprise multiple stacks of semiconductor dies.

20. A semiconductor device, comprising:
a plurality of stacked semiconductor dies, the plurality of semiconductor dies together defining a sidewall;
a plurality of die bond pads on the plurality of semiconductor dies and arranged in columns at the sidewall;
a photo imageable dielectric material covering at least portions of the plurality of stacked semiconductor dies including the sidewall and the plurality of die bond pads; and
means formed through the photo imageable dielectric material for electrically coupling die bond pads on the columns of die bond pads together.
